(19) United States
(12) Patent Application Publication
(10) Pub. No.: US 2008/0304596 A1
(43) Pub. Date: Dec. 11, 2008

(54) Method and System for Receiving Audio, Video and Data Services with ATSC Enabled Television Sets

(76) Inventors: Loke Tan, Newport Coast, CA (US); Lionel J. D'Luna, Irvine, CA (US); Robindra Joshi, Irvine, CA (US)

Correspondence Address: MCANDREWS HELD & MALLOY, LTD, 500 WEST MADISON STREET, SUITE 3400, CHICAGO, IL, 60661, US

(21) Appl. No.: 11/761,504

(22) Filed: Jun. 12, 2007

Related U.S. Application Data
(60) Provisional application No. 60/943,202, filed on Jun. 11, 2007.

(51) Int. Cl. H03D 1/24

(52) U.S. Cl. 375/321

(57) ABSTRACT

Certain aspects of a method and system for receiving audio, video and data services with advanced television systems committee (ATSC) enabled television sets may be provided. Aspects of the method may include conversion of a plurality of received quadrature amplitude modulated (QAM) signals into a plurality of vestigial side band (VSB) signals within a set-top box. The set top box may tune to each of the plurality of received QAM signals and demodulate each of the plurality of received QAM signals into a plurality of bitstreams and demultiplex the plurality of bitstreams. The demultiplexed plurality of bitstreams may be modulated into a plurality of VSB signals. The plurality of VSB signals may be modulated into a plurality of RF signals. One or more of the plurality of RF signals may be communicated to at least one of a plurality of VSB enabled television sets.

### CROSS-REFERENCE TO RELATED APPLICATIONS/INCORPORATION BY REFERENCE

This application makes reference to, claims priority to, and claims the benefit of U.S. Provisional Application Ser. No. 60/943,202 (Attorney Docket No. 17833US01) filed on Jun. 11, 2007.

The above referenced application is hereby incorporated herein by reference in its entirety.

### FIELD OF THE INVENTION

Certain embodiments of the invention relate to digital television systems. More specifically, certain embodiments of the invention relate to a method and system for receiving audio, video and data services with advanced television systems committee (ATSC) enabled television sets.

### BACKGROUND OF THE INVENTION

Television (TV) networks have traditionally utilized analog signal formats to carry video and audio channels to television viewers or subscribers. The television signals may each be modulated at a different radio frequency (RF) and combined or multiplexed for transmission over terrestrial air or a hybrid fiber-coaxial cable network. The customer premise equipment (CPE), such as a TV set or a cable set-top box converter may receive the combined signals, and tune to a particular frequency in order to display the TV channel desired by the viewer.

With various advancements in digital communications and the introduction of digital television (DTV), TV network providers have been replacing or upgrading their transmission and distribution systems to provide new and/or better quality services to their viewers or paid subscribers. In addition to transmitting analog signals, the infrastructure of these upgraded or new systems are also enabled to facilitate the generation and transmission of various digital formats that provide superior picture and sound quality, higher channel capacity, high-speed Internet data services, voice services and/or interactive services. The television network providers may also provide support for legacy systems for both analog and digital television systems. A plurality of analog and/or digital channels may be multiplexed and transmitted by a TV network provider infrastructure, and the CPE may have the capability to determine whether a signal is in an analog format or a digital format. A demodulation or decoding scheme may be utilized to process a channel after detecting whether an incoming signal for a channel is in a digital or an analog format.

The analog TV signals may be defined by the National Television Standards Committee (NTSC), the Phase Alternative Line (PAL) or the Sequential Couleur Avec Memoire (SECAM) systems, and are used in different countries around the world. An analog TV signal may utilize two RF carriers that may be combined in the same channel band. One carrier may be amplitude modulated (AM) with video content, and the other carrier may be frequency modulated (FM) with audio content, for example. An analog TV receiver may be enabled to perform a series of operations comprising, for example, adjusting a signal power, separating video and audio carriers, and locking to each carrier in order to down-convert the signals to baseband. The baseband video signal may be decoded and displayed by achieving horizontal and vertical synchronization and extracting the luminance and color information. After demodulating the received signal, the resulting baseband audio may be decoded, and left, right, surround channels and/or other information may be extracted.

The digital TV signals may utilize a plurality of modulation techniques for transmitting and receiving packetized information comprising one or more digitized and compressed TV programs, Internet data and/or voice data. A digital TV signal may utilize an RF carrier that may be modulated with either quadrature amplitude modulation (QAM) of different levels including quaternary phase shift keying (QPSK), or vestigial sideband (VSB) modulation, among other schemes. A digital TV receiver may be enabled to perform a series of operations comprising, for example, adjusting a signal power, locking to a carrier, and down-converting to baseband. The baseband digital signal may be demodulated by, for example, QAM or VSB. The baseband digital signal may be error corrected, and the baseband digital signal may be synchronized as a valid bit stream. The bit stream may be further decompressed to reproduce the picture and sound, or may be processed as Internet data or voice data.

If a receiver successfully recovers and validates a bit stream from a RF carrier using a QAM scheme, for example, then a QAM signal may have been detected. If the receiver successfully creates and validates a bit stream from the RF carrier using a VSB scheme, for example, then a VSB signal may have been detected. If a receiver successfully locks to the video and audio carriers of an analog signal, then an analog signal, for example, a NTSC TV signal may have been detected. Otherwise, the receiver may not have detected any signal.

The analog receivers may be prone to slow detection of TV signals when the receiver is connected to a cable or over-the-air terrestrial network and may perform a scan of the television channels to detect and possibly store the type of signal present on each channel. Slow detection of the signal on a TV channel is increasingly problematic as advances in digital communications and introduction of digital television have led to an increasing number of television channels and thus an increasing amount of time required to complete a scan of the channels.

In a cable modem used for receiving Internet data, the cable modem receiver may detect only digital QAM signals. When a cable modem has to wait until a valid bit stream is created for each detection attempt, the usual latency associated with a connection increases. Furthermore, the latency due to the waiting process is further exacerbated when the modem has to scan all the available RF channels in order to detect which RF channel contains the appropriate information.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A method and/or system for receiving audio, video and data services with advanced television systems committee (ATSC) enabled television sets, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating an exemplary vestigial side band (VSB) modulator, in accordance with an embodiment of the present invention.

FIG. 2 is a block diagram illustrating an exemplary ATSC receiver set-top box, in accordance with an embodiment of the present invention.

FIG. 3 is a block diagram illustrating an exemplary ATSC digital television set, in accordance with an embodiment of the present invention.

FIG. 4 is a block diagram illustrating an exemplary gateway set-top box, in accordance with an embodiment of the present invention.

FIG. 5 is a block diagram illustrating an exemplary gateway set-top box for receiving audio, video and data services, in accordance with an embodiment of the present invention.

### DETAILED DESCRIPTION OF THE INVENTION

Certain embodiments of the invention may be found in a method and system for receiving audio, video and data services with advanced television systems committee (ATSC) enabled television sets. Aspects of the method and system may comprise conversion of a plurality of received quadrature amplitude modulated (QAM) signals into a plurality of vestigial side band (VSB) signals within a set-top box. The set-top box may be enabled to receive audio, video, or data signals from cable, satellite or phone lines.

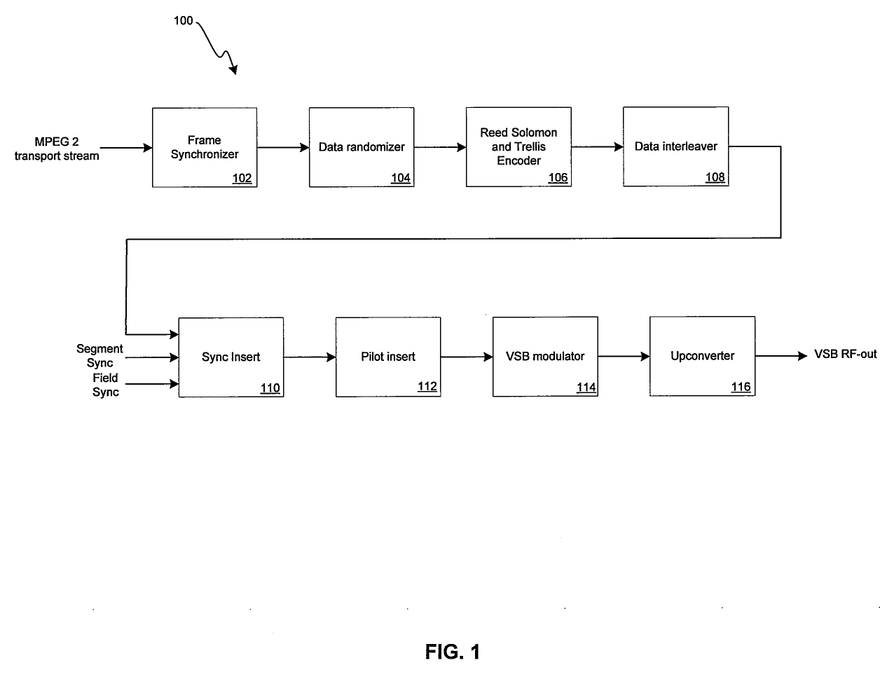

FIG. 1 is a block diagram illustrating an exemplary vestigial side band (VSB) modulator, in accordance with an embodiment of the present invention. Referring to FIG. 1, there is shown a VSB modulator 100. The VSB modulator 100 may comprise a frame synchronizer 102, a data randomizer 104, a Reed-Solomon and Trellis encoder 106, a data interleaver 108, a sync insert block 110, a pilot insert block 112, a VSB modulator 114, and an upconverter 116.

The frame synchronizer 102 may comprise suitable logic, circuitry, and/or code that may be enabled to synchronize to the received MPEG-2 transport bitstream packets. The frame synchronizer 102 may be enabled to identify a start and end points of each received MPEG-2 packet by utilizing its sync byte. This sync byte may be discarded and replaced with an ATSC segment sync. The data randomizer 104 may comprise suitable logic, circuitry, and/or code that may be enabled to utilize, for example, a pseudo random number generator to scramble the bitstream to generate a flat, noise-like spectrum that maximizes channel bandwidth efficiency and reduces possible interference with other DTV and NTSC channels.

The Reed-Solomon and Trellis encoder 106 may comprise suitable logic, circuitry, and/or code that may be enabled to provide forward error correction for the received data stream. The Reed-Solomon and Trellis encoder 106 may be enabled to detect and correct any errors, which may occur in the received bit stream. The data interleaver 108 may comprise suitable logic, circuitry, and/or code that may be enabled to scramble the sequential order of the data stream in order to minimize sensitivity to burst-type interference. The sync insert block 110 may comprise suitable logic, circuitry, and/or code that may be enabled to receive a segment sync signal and a field sync signal in order to aid a VSB receiver to locate and demodulate the transmitted signal. The pilot insert block 112 may comprise suitable logic, circuitry, and/or code that may be enabled to receive a pilot insert signal in order to lock on to the transmitted data.

The VSB modulator 114 may comprise suitable logic, circuitry, and/or code that may be enabled to amplitude modulate the baseband signal onto an intermediate frequency carrier. The VSB modulator 114 may comprise a Nyquist VSB filter to filter the received signal in order to remove redundant information. The upconverter 116 may comprise suitable logic, circuitry, and/or code that may be enabled to upconvert the VSB intermediate frequency signal to a ultra high frequency (UHF) or a very high frequency (VHF) signal.

The VSB modulator 100 may be enabled to offer one or more modes of operation, for example, a terrestrial broadcast mode and a high data rate mode. In the terrestrial broadcast mode, the VSB modulator 100 may be enabled to provide maximum coverage supporting a high-definition TV (HDTV) signal or multiple standard definition TV (SDTV) signals in a 6 MHz channel, for example. In both the modes, the VSB modulator 100 may be enabled to share the same pilot, symbol rate, data frame structure, interleaving, Reed-Solomon coding, and synchronization pulses.

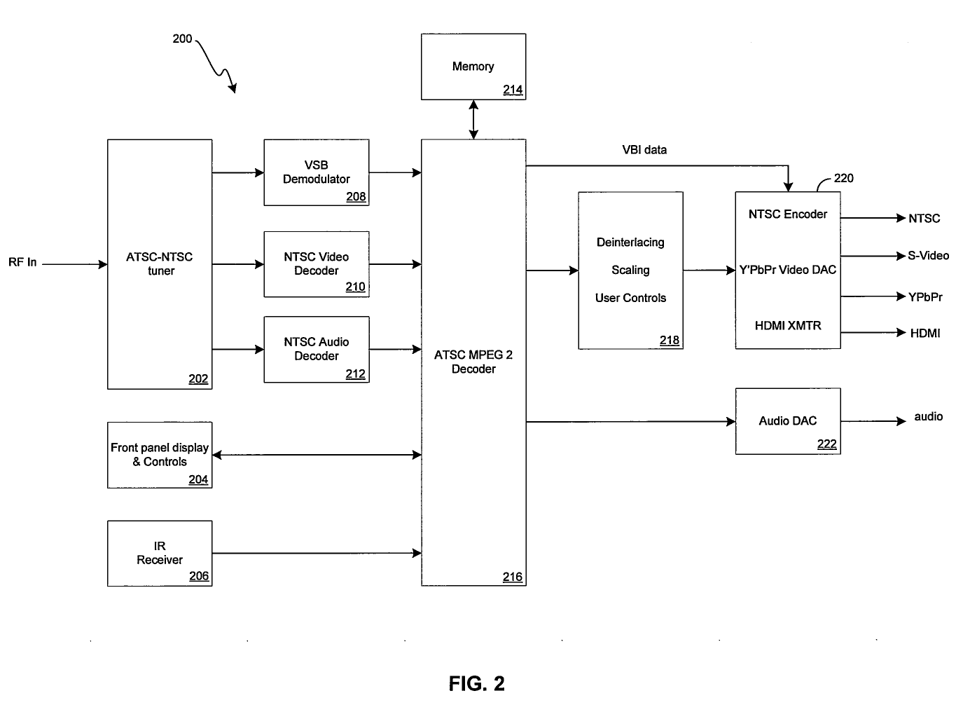

FIG. 2 is a block diagram illustrating an exemplary ATSC receiver set-top box, in accordance with an embodiment of the present invention. Referring to FIG. 2, there is shown a ATSC receiver set-top box 200. The ATSC receiver set-top box 200 may comprise a ATSC-NTSC tuner 202, a front panel display and controls block 204, an infrared (IR) receiver 206, a VSB demodulator 208, a NTSC video decoder 210, a NTSC audio decoder 212, a memory 214, a ATSC MPEG-2 decoder 216, a deinterlacing block 218, an encoder 220, and an audio digital to analog converter (DAC) 222.

The ATSC-NTSC tuner 202 may comprise suitable logic, circuitry and/or code that may be enabled to allow ATSC or NTSC signals in a desired frequency range and reject signals that are out of the desired frequency range. Accordingly, the ATSC-NTSC tuner 202 may comprise one or more passband filters for allowing signals in the desired range and rejecting signals outside of the desired range. The ATSC-NTSC tuner 202 may be coupled directly to, for example, a cable television wall outlet via, for example, a coaxial cable, or an over-the-air terrestrial television antenna.

The front panel display and controls block 204 may comprise suitable logic, circuitry and/or code that may be enabled to control the front panel display of a television set. The IR receiver 206 may comprise suitable logic, circuitry and/or code that may be enabled to process received IR signals.

The VSB demodulator 208 may comprise suitable logic, circuitry and/or code that may be enabled to convert a received RF signal into an IF signal. This IF signal may be converted into a base band signal and may be filtered by a plurality of low-pass filters. The filtered signal may be converted to a digital signal and demodulated into a VSB signal. The NTSC video decoder 210 may comprise suitable logic, circuitry and/or code that may be enabled to decode the received RF signal into a NTSC video signal and communicate the decoded NTSC video signal to the ATSC MPEG-2 decoder 216. The NTSC audio decoder 212 may comprise suitable logic, circuitry and/or code that may be enabled to decode the received RF signal into a NTSC audio signal and communicate the decoded NTSC audio signal to the ATSC MPEG-2 decoder 216.

The ATSC MPEG-2 decoder 216 may comprise suitable logic, circuitry and/or code that may be enabled to receive the demodulated VSB signals, decoded NTSC audio and video signals and decode the received signals into ATSC audio and video signals. The ATSC MPEG-2 decoder 216 may be enabled to communicate the generated ATSC audio signal to the audio DAC 222. The ATSC MPEG-2 decoder 216 may be enabled to communicate the generated ATSC video signal to the deinterlacing block 218 and the vertical blanking interval (VBI) data to the encoder 220. The time interval between incorporation of pulses to maintain signal synchronization between a transmitter and a receiver and to deactivate the beam while traveling from the bottom of a screen at the end of one field to the top of a screen for the start of a next field may be referred to as the vertical blanking interval (VBI).

The deinterlacing block 218 may comprise suitable logic, circuitry and/or code that may be enabled to deinterlace and scale the received video signal and communicate the deinterlaced signal to the encoder 220. The encoder 220 may comprise suitable logic, circuitry and/or code that may be enabled to encode the received signals in one of a plurality of formats. For example, the encoder 220 may comprise a NTSC encoder to encode the signals in the NTSC video format. The encoder 220 may comprise a Y′PbPr encoder video DAC to generate an analog or S-video output signal. The encoder 220 may comprise a high-definition multimedia interface (HDMI) transmitter that may generate a HDMI output signal. The audio DAC 222 may comprise suitable logic, circuitry and/or code that may be enabled to generate an output analog audio signal.

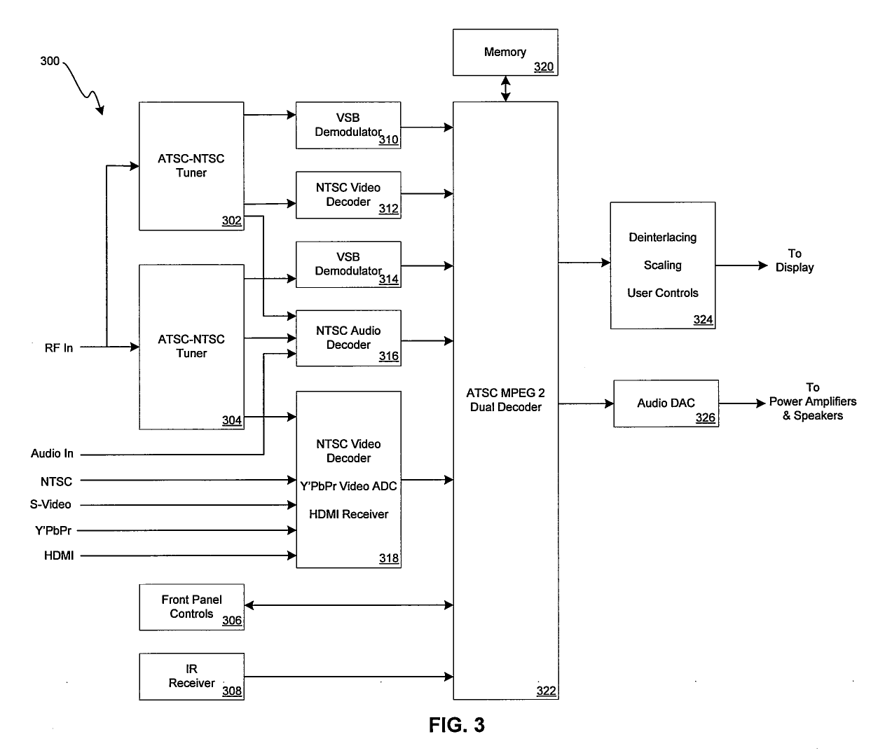

FIG. 3 is a block diagram illustrating an exemplary ATSC digital television set, in accordance with an embodiment of the present invention. Referring to FIG. 3, there is shown a ATSC digital television set 300. The ATSC digital television set 300 may comprise a plurality of ATSC-NTSC tuners 302 and 304, a front panel controls block 306, an infrared (IR) receiver 308, a plurality of VSB demodulators 310 and 314, a NTSC video decoder 312, a NTSC audio decoder 316, a decoder 318, a memory 320, a ATSC MPEG-2 dual decoder 322, a deinterlacing block 324, and an audio digital to analog converter (DAC) 326.

The plurality of ATSC-NTSC tuners 302 and 304 may comprise suitable logic, circuitry and/or code that may be enabled to allow ATSC or NTSC signals in a desired frequency range and reject signals that are out of the desired frequency range. Accordingly, the ATSC-NTSC tuners 302 and 304 may comprise one or more passband filters for allowing signals in the desired range and rejecting signals outside of the desired range. The ATSC-NTSC tuners 302 and 304 may receive a RF input signal and may be coupled directly to, for example, a cable television wall outlet via, for example, a coaxial cable, or an over-the-air terrestrial television antenna.

The front panel controls block 306 may comprise suitable logic, circuitry and/or code that may be enabled to control the front panel display of a television set or monitor. The IR receiver 308 may comprise suitable logic, circuitry and/or code that may be enabled to process received IR signals.

The plurality of VSB demodulators 310 and 314 may comprise suitable logic, circuitry and/or code that may be enabled to convert a received RF signal into an IF signal. This IF signal may be converted into a base band signal and may be filtered by a plurality of low-pass filters. The filtered signal may be converted to a digital signal and demodulated into a VSB signal. The NTSC video decoder 312 may comprise suitable logic, circuitry and/or code that may be enabled to decode the received RF signal into a NTSC video signal and communicate the decoded NTSC video signal to the ATSC MPEG-2 dual decoder 322. The NTSC audio decoder 316 may comprise suitable logic, circuitry and/or code that may be enabled to decode the received audio signal into a NTSC audio signal and communicate the decoded NTSC audio signal to the ATSC MPEG-2 dual decoder 322.

The decoder 318 may comprise suitable logic, circuitry and/or code that may be enabled to decode the received signals in one of a plurality of formats. For example, the decoder 318 may comprise a NTSC decoder to decode the NTSC video signals. The decoder 318 may comprise a Y′PbPr decoder video ADC to receive a S-video or Y′PbPr signal and generate an analog output signal. The decoder 318 may comprise a high-definition multimedia interface (HDMI) receiver that may receive a HDMI input signal and generate a decoded output signal to the ATSC MPEG-2 dual decoder 322.

The ATSC MPEG-2 dual decoder 322 may comprise suitable logic, circuitry and/or code that may be enabled to receive the demodulated VSB signals, decoded NTSC audio and video signals and decode the received signals into ATSC audio and video signals. The ATSC MPEG-2 dual decoder 322 may be enabled to communicate the generated ATSC audio signal to the audio DAC 326. The ATSC MPEG-2 dual decoder 322 may be enabled to communicate the generated ATSC video signal to the deinterlacing block 324. The deinterlacing block 324 may comprise suitable logic, circuitry and/or code that may be enabled to deinterlace and/or scale the received video signal and communicate the deinterlaced signal to a display. The audio DAC 326 may comprise suitable logic, circuitry and/or code that may be enabled to generate an analog audio signal to a power amplifier and/or speakers.

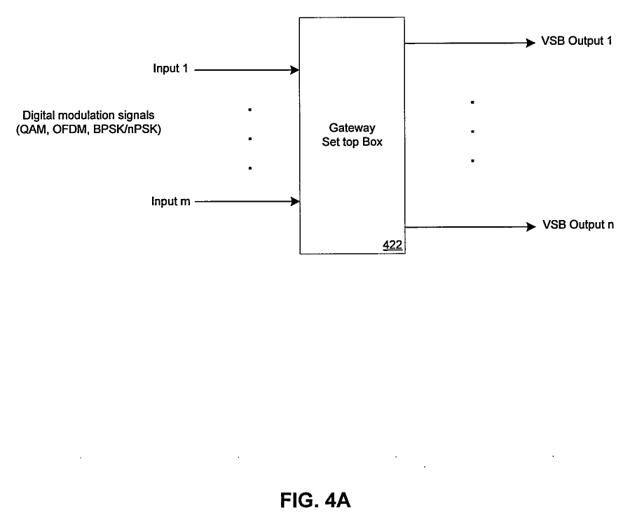

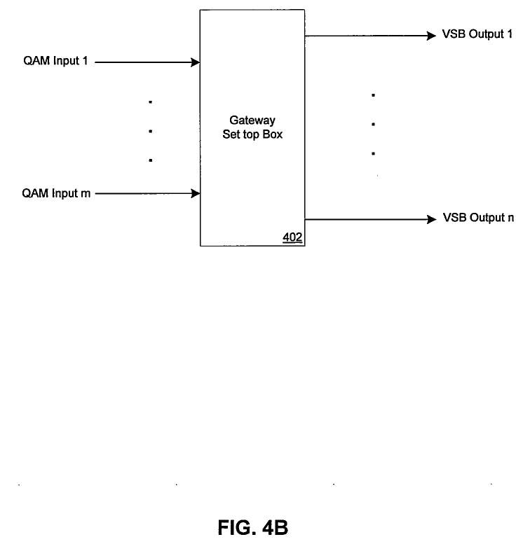

FIG. 4A is a block diagram illustrating an exemplary gateway set-top box, in accordance with an embodiment of the present invention. Referring to FIG. 4A, there is shown a gateway set-top box 422.

The gateway set-top box 422 may comprise suitable logic, circuitry and/or code that may be enabled to receive a plurality of digital modulation signals, for example, quadrature amplitude modulated (QAM) signals, orthogonal frequency division multiplexing (OFDM) signals, binary phase shift keying (BPSK)/nPSK and other digital modulation signals, 1 . . . m from, for example, from a plurality of sources such as cable, satellite, phone, wireless, or Fiber. The gateway set-top box 422 may be enabled to convert the received plurality of digital modulation signals 1 . . . m into a plurality of vestigial side-band (VSB) signals 1 . . . n. For example, the gateway set-top box 422 may be enabled to receive sixteen QAM signals and convert the received sixteen QAM signals into 80 VSB signals. The plurality of VSB signals may be input into a plurality of VSB enabled television sets.

FIG. 4B is a block diagram illustrating an exemplary gateway set-top box, in accordance with an embodiment of the present invention. Referring to FIG. 4B, there is shown a gateway set-top box 402.

The gateway set-top box 402 may comprise suitable logic, circuitry and/or code that may be enabled to receive a plurality of quadrature amplitude modulated (QAM) signals 1 . . . m from, for example, from a plurality of sources such as cable, satellite, phone, wireless, or Fiber. The gateway set-top box 402 may be enabled to convert the received plurality of QAM signals 1 . . . m into a plurality of vestigial side-band (VSB) signals 1 . . . n. For example, the gateway set-top box 402 may be enabled to receive sixteen QAM signals and convert the received sixteen QAM signals into 80 VSB signals. The plurality of VSB signals may be input into a plurality of VSB enabled television sets.

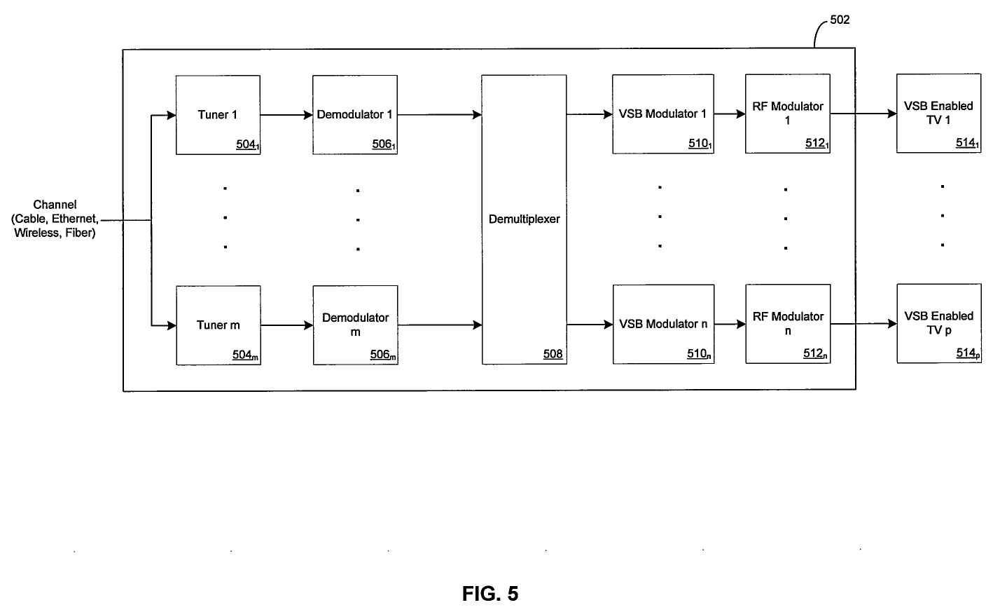

FIG. 5 is a block diagram illustrating an exemplary gateway set-top box for receiving audio, video and data services, in accordance with an embodiment of the present invention. Referring to FIG. 5, there is shown a gateway set-top box 502 and a plurality of VSB enabled television sets 514_{1 . . . q}. The gateway set-top box 502 may comprise a plurality of tuners 504_{1 . . . m}, a plurality of demodulators 506_{1 . . . m}, a demultiplexer 508, a plurality of VSB modulators 510_{1 . . . n} and a plurality of RF modulators 512_{1 . . . n}.

The plurality of tuners 504_{1 . . . m} may comprise suitable logic, circuitry and/or code that may be enabled to allow signals in a desired frequency range and reject signals that are outside the desired frequency range. The plurality of tuners 504_{1 . . . m} may comprise one or more passband filters for allowing signals in the desired range and rejecting signals outside of the desired range. For example, the gateway set-top box 502 may comprise 16 tuners, and each tuner may be enabled to receive an input signal from a cable. The plurality of tuners 504_{1 . . . m} may receive a RF input signal and may be coupled directly to, for example, a cable television wall outlet via, for example, a coaxial cable, or an over-the-air terrestrial television antenna. Notwithstanding, the plurality of tuners 504_{1 . . . m} may be enabled to receive an input signal from a DVD, VCR, or other suitable data format.

The plurality of demodulators 506_{1 . . . m} may comprise suitable logic, circuitry and/or code that may be enabled to demodulate the plurality of received digital modulation signals, for example, QAM signals into a plurality of bitstreams. For example, the gateway set-top box 502 may comprise sixteen QAM demodulators, and each QAM demodulator may be enabled to demodulate a received QAM signal into a bitstream. The demultiplexer 508 may comprise suitable logic, circuitry and/or code that may be enabled to demultiplex a plurality of received bitstreams from the plurality of demodulators 506_{1 . . . m}. For example, the demultiplexer 508 may be enabled to demultiplex 16 bitstreams received from the plurality of demodulators 506_{1 . . . m} and generate 80 bitstreams to the plurality of VSB modulators 510_{1 . . . n}. The demultiplexer 508 may be enabled to generate a plurality of bitstreams to a plurality of VSB modulators 510_{1 . . . n}.

The plurality of VSB modulators 510_{1 . . . n} may comprise suitable logic, circuitry and/or code that may be enabled to modulate the plurality of received bitstreams from the demultiplexer 508 and generate a plurality of VSB modulated signals. For example, the gateway set-top box 502 may comprise 80 VSB modulators, and each VSB modulator may be enabled to modulate the received bitstream into a VSB signal. The plurality of RF modulators 512_{1 . . . n} may comprise suitable logic, circuitry and/or code that may be enabled to modulate and upconvert the VSB modulated intermediate frequency signals to a plurality of ultra high frequency (UHF) signals or a plurality of very high frequency (VHF) signals. For example, the gateway set-top box 502 may comprise 80 RF modulators, and each RF modulator may be enabled to modulate the received VSB modulated signal into a UHF or VHF signal. The plurality of VSB enabled television sets 514_{1 . . . q} may comprise suitable logic, circuitry and/or code that may be enabled to receive the plurality of VHF or UHF signals from the gateway set-top box 502.

In accordance with an embodiment of the invention, the gateway set-top box 502 may be enabled to receive digitally modulated audio, video, and data services via cable, satellite, wireless, Fiber or phone lines, for example, via digital subscriber line (DSL) or asymmetric digital subscriber line (ADSL). In another embodiment, the gateway set-top box 502 may also be enabled to receive digitally modulated audio, video, and data services via wireless personal area networks (PAN), local area networks (LAN), wide are networks (WAN) such as 802.11, ultra wideband (UWB), local multipoint distribution system (LMDS), multipoint multi-service distribution service (MMDS), WiMAX, code division multiple access (CDMA), general packet radio service (GPRS) and other telecommunication networks. In another embodiment, the gateway set-top box 502 may also be enabled to receive digitally modulated audio, video, and data services via wireless broadcast networks such as digital video broadcasting-handheld (DVB-H), Mediaflow, integrated services digital broadcasting-terrestrial (ISDBT), terrestrial digital multimedia broadcasting (TDMB) and other broadcast networks. In another embodiment, the gateway set-top box 502 may also be enabled to receive digitally modulated audio, video, and data services via optical fiber distribution networks such as passive optical networks (PONs). The gateway set-top box 502 may be enabled to generate ATSC enabled audio, video, or data content without MPEG-2 decoding.

In accordance with an embodiment of the invention, a method and system for receiving audio, video and data services with advanced television systems committee (ATSC) enabled television sets may include conversion of a plurality of received quadrature amplitude modulated (QAM) signals into a plurality of vestigial side band (VSB) signals within a set-top box, for example, the gateway set-top box 502. The gateway set-top box 502 may be enabled to receive audio, video, or data signals from cable, satellite or phone lines.

The plurality of tuners 504_{1 . . . m} may be enabled to allow or tune signals in a desired frequency range and reject signals that are outside the desired frequency range. The plurality of demodulators 506_{1 . . . m} may be enabled to demodulate the plurality of received digital modulation signals, for example, QAM signals into a plurality of bitstreams. The demultiplexer 508 may be enabled to demultiplex a plurality of received bitstreams from the plurality of demodulators 506_{1 . . . m}. The demultiplexer 508 may be enabled to generate a plurality of bitstreams to a plurality of VSB modulators 510_{1 . . . n}. The plurality of VSB modulators 510_{1 . . . n} may be enabled to modulate the plurality of received bitstreams from the demultiplexer 508 and generate a plurality of VSB modulated signals. The plurality of RF modulators 512_{1 . . . n} may be enabled to modulate and upconvert the VSB modulated intermediate frequency signals to a plurality of UHF or VHF signals. The plurality of RF modulators 512_{1 . . . n} may be enabled to communicate the plurality of VHF or UHF signals from the gateway set-top box 502 to the plurality of VSB enabled television sets 514_{1 . . . q}.

Another embodiment of the invention may provide a machine-readable storage, having stored thereon, a computer program having at least one code section executable by a machine, thereby causing the machine to perform the steps as described above for receiving audio, video and data services with advanced television systems committee (ATSC) enabled television sets.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for processing signals, the method comprising:
converting within a set-top box, a plurality of received quadrature amplitude modulated (QAM) signals into a plurality of vestigial side band (VSB) signals.

2. The method according to claim 1, comprising tuning to each of said plurality of received QAM signals.

3. The method according to claim 1, comprising demodulating each of said plurality of received QAM signals into a plurality of bitstreams.

4. The method according to claim 3, comprising demultiplexing said plurality of bitstreams.

5. The method according to claim 4, comprising modulating said demultiplexed said plurality of bitstreams into said plurality of VSB signals.

6. The method according to claim 5, comprising modulating said plurality of VSB signals into a plurality of RF signals.

7. The method according to claim 6, comprising communicating one or more of said plurality of RF signals to at least one of a plurality of VSB enabled television sets.

8. A machine-readable storage having stored thereon, a computer program having at least one code section for processing signals, the at least one code section being executable by a machine for causing the machine to perform steps comprising:
converting within a set-top box, a plurality of received quadrature amplitude modulated (QAM) signals into a plurality of vestigial side band (VSB) signals.

9. The machine-readable storage according to claim 8, wherein said at least one code section comprises code for tuning to each of said plurality of received QAM signals.

10. The machine-readable storage according to claim 8, wherein said at least one code section comprises code for demodulating each of said plurality of received QAM signals into a plurality of bitstreams.

11. The machine-readable storage according to claim 10, wherein said at least one code section comprises code for demultiplexing said plurality of bitstreams.

12. The machine-readable storage according to claim 11, wherein said at least one code section comprises code for modulating said demultiplexed said plurality of bitstreams into said plurality of VSB signals.

13. The machine-readable storage according to claim 12, wherein said at least one code section comprises code for modulating said plurality of VSB signals into a plurality of RF signals.

14. The machine-readable storage according to claim 13, wherein said at least one code section comprises code for communicating one or more of said plurality of RF signals to at least one of a plurality of VSB enabled television sets.

15. A system for processing signals, the system comprising:
one or more circuits that enables conversion of a plurality of received quadrature amplitude modulated (QAM) signals into a plurality of vestigial side band (VSB) signals within a set-top box.

16. The system according to claim 15, wherein said one or more circuits enables tuning to each of said plurality of received QAM signals.

17. The system according to claim 15, wherein said one or more circuits enables demodulation of each of said plurality of received QAM signals into a plurality of bitstreams.

18. The system according to claim 17, wherein said one or more circuits enables demultiplexing of said plurality of bitstreams.

19. The system according to claim 18, wherein said one or more circuits enables modulation of said demultiplexed said plurality of bitstreams into said plurality of VSB signals.

20. The system according to claim 19, wherein said one or more circuits enables modulation of said plurality of VSB signals into a plurality of RF signals.

21. The system according to claim 20, wherein said one or more circuits enables communication of one or more of said plurality of RF signals to at least one of a plurality of VSB enabled television sets.
